(19) United States
(12) Patent Application Publication
(10) Pub. No.: US 2022/0328458 A1
(43) Pub. Date: Oct. 13, 2022

(54) LED MODULE AND LED DISPLAY DEVICE

(71) Applicant: CHONGQING KONKA PHOTOELECTRIC TECHNOLOGY RESEARCH INSTITUTE CO., LTD., Chongqing (CN)

(72) Inventor: CHING-CHUNG CHEN, Chongqing (CN)

(21) Appl. No.: 17/256,149

(22) PCT Filed: Sep. 6, 2019
(86) PCT No.: PCT/CN2019/104765

§ 371 Date: Dec. 24, 2020

(51) Int. Cl. H01L 25/075

(52) U.S. Cl. CPC H01L 25/0753

(57) ABSTRACT

The disclosure relates to an LED module and an LED display device, including a circuit substrate, and red LEDs, green LEDs and blue LEDs provided on the circuit substrate, among which the number of LEDs with at least one color is more than one; the red LEDs, the green LEDs and the blue LEDs are arranged in the same row or the same column, and the LEDs of the same color are adjacently arranged. According to the disclosure, the Red-Green-Blue LEDs in the LED module are adjusted in the number and arranged with respect to their positions, so that the color contrast and brightness of the LED module are improved.

### TECHNICAL FIELD

The disclosure relates to the technical field of LEDs, in particular to an LED module and an LED display device.

### BACKGROUND

An LED module refers to a product formed by arranging a certain number of light-emitting diodes on a circuit substrate according to some rules and then packaging. The conventional LED module usually utilizes colors of red, green and blue to achieve the visual effects of mixed light and white light; however, if these three colors show little distinction from each other in display, as shown in FIG. 1, the LED module may, as a result, have poor color contrast and reduced visual prominence.

Therefore, there remains a need in the prior art for improvement.

### BRIEF SUMMARY

In view of the defects of the prior art, it's an object of the disclosure to provide an LED module and an LED display device to solve the problems of poor color contrast and reduced visual prominence of the conventional LED module.

The technical solution of the disclosure is as follows:

an LED module and an LED display device, comprising a circuit substrate, and red LEDs, green LEDs and blue LEDs provided on the circuit substrate, among which the number of LEDs with at least one color is more than one; the red LEDs, the green LEDs and the blue LEDs being arranged in the same row or the same column, and the LEDs of the same color being adjacently arranged.

The aforementioned LED module, comprising two red LEDs, one green LED and one blue LED, wherein the two red LEDs are arranged adjacent to each other, and the green LED and the blue LED are respectively arranged on two sides of the two adjacent red LEDs.

The aforementioned LED module, comprising two green LEDs, one red LED and one blue LED, wherein the two green LEDs are arranged adjacent to each other, and the red LED and the blue LED are respectively arranged on two sides of the two adjacent green LEDs.

The aforementioned LED module, comprising two red LEDs which are adjacently arranged, two green LEDs which are adjacently arranged and one blue LED, wherein the two adjacent red LEDs and the two adjacent green LEDs are located on two sides of the blue LED.

The aforementioned LED module, wherein a distance between the LEDs of the same color is d, a distance between the LEDs with different colors is D, and d is less than D.

The aforementioned LED module, wherein a distance between light emitting surfaces of the more-than-one LEDs of the same color and the circuit substrate is H, a distance between a light emitting surface of the one-numbered LED and the circuit substrate is h, and h is less than H.

The aforementioned LED module, wherein a preset substrate with the height of a is provided on the circuit substrate, the more-than-one LEDs of the same color and having a height of b are provided on the preset substrate, and a+b=H.

An LED module, comprising a circuit substrate, and at least four red LEDs, at least four green LEDs and at least four blue LEDs provided on the circuit substrate, wherein the red LEDs are arranged in an n*m matrix, two sides of each row of the red LEDs are respectively provided with blue LEDs and green LEDs, and two sides of each column of the red LEDs are respectively provided with blue LEDs and green LEDs; and both n and m are greater than or equal to 2.

The aforementioned LED module, wherein one side of the red LEDs is provided with a blue LED alternating with a green LED.

The aforementioned LED module, wherein one side of the red LEDs is provided with blue LEDs arranged adjacently or green LEDs arranged adjacently.

The aforementioned LED module, comprising four red LEDs, four green LEDs and four blue LEDs, wherein the four red LEDs are arranged in a 2*2 matrix, and the left and right sides of a first row of red LEDs and a second row of red LEDs are respectively provided with a green LED and a blue LED; the upper and lower sides of the first column of red light LEDs and the second column of red light LEDs are respectively provided with a green light LED and a blue light LED.

The aforementioned LED module, comprising four red LEDs, four green LEDs and four blue LEDs, wherein the four red LEDs are arranged in a 2*2 matrix, the left and right sides of a first row of red LEDs are respectively provided with a blue LED and a green LED, and the left and right sides of a second row of red LEDs are respectively provided with a green LED and a blue LED; the upper and lower sides of the first column of red light LEDs are respectively provided with a blue light LED and a green light LED, and the upper and lower sides of the second column of red light LEDs are respectively provided with a green light LED and a blue light LED.

The aforementioned LED module, wherein a distance between the red LEDs is d, a distance from the red LED to the blue LED and to the green LED is D, and d is less than D.

The aforementioned LED module, wherein a distance between light emitting surfaces of the red LEDs and the circuit substrate is H, a distance from light emitting surfaces of the blue LEDs and from the green LEDs to the circuit substrate is h, and h is less than H.

An LED display device, comprising an LED module according to the present disclosure.

The beneficial effects are as follows: according to the disclosure, the Red-Green-Blue LEDs in the LED module are adjusted in the number and arranged with respect to their positions, so that the color contrast and brightness of the LED module are improved.

### BRIEF DESCRIPTION OF THE DRAWINGS

FIG. 1 is a schematic diagram of color contrast for a conventional LED module.

FIG. 2 is a side cross-sectional view of a first embodiment of an LED module of the present disclosure.

FIG. 3 is a side cross-sectional view of a second embodiment of an LED module of the present disclosure.

FIG. 4 is a side cross-sectional view of a third embodiment of an LED module of the present disclosure.

FIG. 5 is a schematic view showing a top view structure of a fourth embodiment of an LED module according to the present disclosure.

### DETAILED DESCRIPTION OF EMBODIMENTS

The disclosure provides an LED module and an LED display device, and in order to explain the object, technical solution and effects of the disclosure more clearly and expressively, detailed description is given below to further illustrate the disclosure. It is to be understood that the specific embodiments described herein are merely illustrative of the present disclosure and are not intended to be limiting.

The conventional LED module has the problems of poor color contrast and reduced visual prominence. Color contrast can be improved by controlling the current intensity of the Red-Green-Blue(RGB)LEDs, however, in this way, it requires not only to redesign the circuit structure, but also to cooperate with a complex control scheme, which greatly increases the design costs and the operation complexity.

In order to address the problems of the conventional LED module, the embodiment of the disclosure provides an LED module, including a circuit substrate and red LEDs, green LEDs and blue LEDs provided on the circuit substrate, among which the number of LEDs with at least one color is more than one; the red LEDs, the green LEDs and the blue LEDs are arranged in the same row or the same column, and the LEDs of the same color are adjacently arranged.

Specifically, color contrast refers to the ratio of the brightest regions to the darkest regions of a projection image, a larger ratio indicates more gradual change levels from black to white, which represents a richer color performance. The influence of color contrast on visual effect is very critical. Generally speaking, a greater contrast indicates a clearer image and brighter color, while less contrast degrades the entire image. Therefore, strong contrast helps a lot on image sharpness, detail presentation and gray level performance; a stronger contrast contributes to a better image effect and improved color saturation, while a reduced contrast results in a blurry image and dimmed color. The light intensity is inversely proportional to the wavelength of light, and the wavelength of the blue light is less than the wavelength of the green light and less than the wavelength of the red light (the wavelength of the blue light<the wavelength of the green light<the wavelength of the red light), which means that light intensity of the blue light emitted by the blue LED is the strongest, second to which is light intensity of the green light emitted by the green LED, and light intensity of the red light emitted by the red LED is the weakest in the LED module.

In the embodiment, the number of the LEDs with weaker light intensity in the LED module is increased, and the LEDs of the same color with weaker light intensity are adjacently arranged, so that the light intensity of the LEDs with weaker light intensity is superposed and can be adaptive to the light intensity of another LED or two LEDs with stronger light intensity, so as to improve the color contrast and the brightness of the LED module.

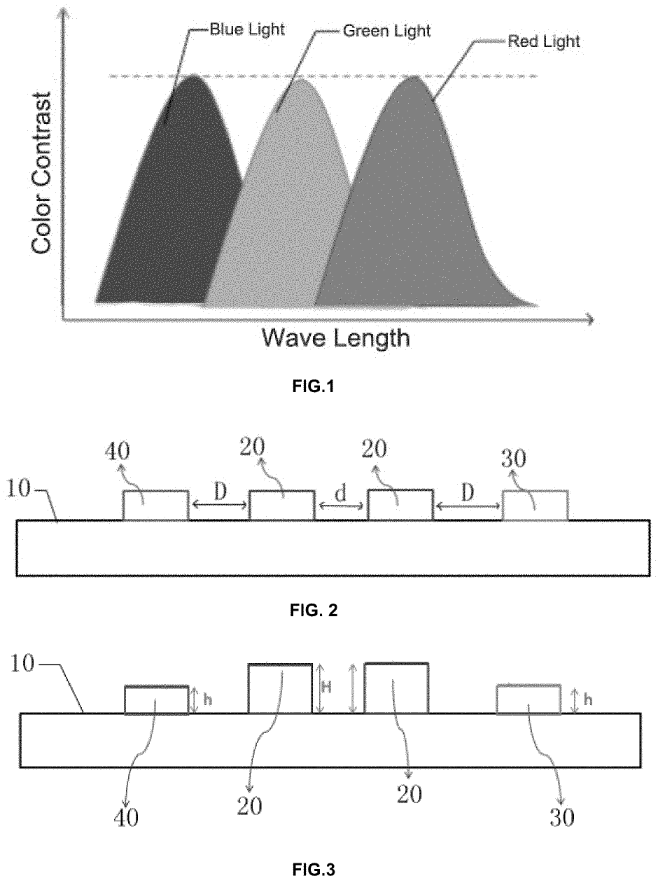

In some embodiments, as shown in FIG. 2, the LED module includes a circuit substrate 10, and includes two red LEDs 20, one green LED 30 and one blue LED 40 provided on the circuit substrate 10, wherein the two red LEDs 20 are arranged adjacent to each other, the green LED 30 and the blue LED 40 are arranged on both sides of the two adjacent red LEDs 20, respectively. In the embodiment, due to the fact that light intensity of the light emitted by the red LED is the weakest, the two red LEDs are provided in the LED module to enhance the light intensity of the red light so as to enable the LED module to have better color contrast, and the two red LEDs are arranged adjacent to each other. Furthermore, in order to improve the uniformity of the white light in the LED module, the green LED and the blue LED are respectively arranged on two sides of the two adjacent red LEDs.

In some embodiments, taking the LED module shown in FIG. 2 as an example, in order to enhance the display contrast ratio of the red light, the distance between the two adjacent red LEDs is set as d, the distances from the red LED to the green LED and to the blue LED are set as D, and d is less than D. In the embodiment, the distance between the two adjacent red LEDs is smaller than the distance from the red LED to the green LED or to the blue LED, so the red light emitted by the two adjacent red LEDs is concentrated, the display contrast ration of the red light is enhanced and can be adaptive to the display contrast ratios of the blue light emitted by the blue LED and the green light emitted by the green LED, and thus the overall color contrast ratio of the LED module is improved.

In some embodiments, taking the LED module shown in FIG. 2 as an example, in order to enhance the display contrast ratio of red light, the light emitting surfaces of the two adjacent red LEDs are disposed at a distance H from the circuit substrate, the light emitting surfaces of the blue LED and the green LED are disposed at a distance h from the circuit substrate, and h is less than H. As shown in FIG. 3, in the embodiment, the height of the red LED is increased, the light emitting surface of the red LED is closer to the display screen, so the display contrast ratio of the red light is enhanced and can be adaptive to the display contrast ratios of the blue light emitted by the blue LED and the green light emitted by the green LED, and thus the overall color contrast ratio of the LED module is improved.

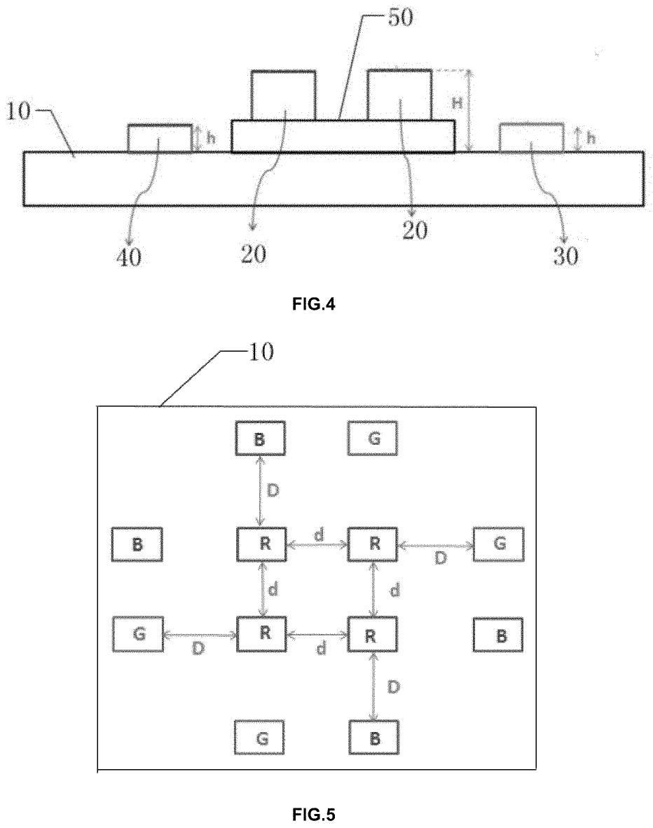

In some embodiments, as shown in FIG. 4, a preset substrate 50 having a height a is provided on the circuit substrate 10, and a red LED having a height b is provided on the preset substrate 50, with a+b=H. In the embodiment, the height of the red LED is increased by adding the preset substrate, so that the light emitting surface of the red LED is closer to the display screen, the display contrast ratio of the red light is enhanced and can be adaptive to the display contrast ratios of the blue light emitted by the blue LED and the green light emitted by the green LED, and thus the overall color contrast ratio of the LED module is improved.

In some embodiments, the LED module includes two green LEDs, one red LED and one blue LED, wherein the two green LEDs are arranged adjacently, the red LED and the blue LED are arranged on both sides of the adjacent two green LEDs respectively. In this embodiment, since the intensity of the green light emitted by the green light LED is weaker than that of the blue light, in order to enhance the intensity of the green light so that the LED module has a better color contrast, two green light LEDs are provided in the LED module, and the two green light LEDs are arranged adjacent to each other. Furthermore, in order to improve the uniformity of the white light in the LED module, the red LED and the blue LED are respectively arranged on two sides of the two adjacent green LEDs.

In the embodiment, in order to enhance the display contrast ratio of the green light, the distance between the two adjacent green LEDs can also be set to be smaller than the distance from the green LEDs to the red LED or to the blue LED, so that the green light emitted by the two adjacent green LEDs is concentrated, the display contrast ratio of the green light is enhanced and can be adaptive to the display contrast ratios of the blue light emitted by the blue LEDs and the red light emitted by the red LEDs, and thus the overall color contrast ratio of the LED module is improved.

In some embodiments, in order to enhance the display contrast ratio of green light, the light emitting surfaces of the two adjacent green LEDs are disposed at a distance H from the circuit substrate, the light emitting surfaces of the blue LED and the red LED are disposed at a distance h from the circuit substrate, and h is less than H. The height of the green LED is increased, the light emitting surface of the green LED is closer to the display screen, so the display contrast ratio of the green light is enhanced and can be adaptive to the display contrast ratios of the blue light emitted by the blue LED and the red light emitted by the red LED, and thus the overall color contrast ratio of the LED module is improved.

In some embodiments, the LED module includes two red LEDs arranged adjacently, two green LEDs arranged adjacently, and one blue LED, wherein the two adjacent red LEDs, and the two adjacent green LEDs are located on both sides of the blue LED. In the embodiment, since the light intensity of the red light emitted by the red light LED and the light intensity of the green light emitted by the green light LED are weaker than that of the blue light, in order to enhance the light intensity of the red light and the green light so that the LED module has a better color contrast, two red light LEDs and two green light LEDs are provided in the LED module, the two green light LEDs are arranged adjacent to each other, and the two red light LEDs are also arranged adjacent to each other. Furthermore, in order to improve the uniformity of the white light in the LED module, the two red LEDs and the two green LEDs are respectively arranged on two sides of the blue LED.

In the embodiment, in order to enhance the display contrast ratios of red light and green light, the distance between the two adjacent red LEDs can be set to be smaller than the distance from the blue LED to the red LED or to the green LED, and the distance between the two adjacent green LEDs can be set to be smaller than the distance from the blue LED to the red LED or to the green LED, so that the green light emitted by the two adjacent green light LEDs and the red light emitted by the two adjacent red light LEDs are concentrated, and the display contrast ratios of the green light and the red light are enhanced and can be adaptive to the display contrast ratio of the blue light emitted by the blue light LED, and thus the overall color contrast ratio of the LED module is improved.

In the embodiment, in order to enhance the display contrast ratios of the red light and the green light, the light emitting surfaces of the two adjacent green LEDs and the two adjacent red LEDs are disposed at a distance H from the circuit substrate, the light emitting surface of the blue LED is disposed at a distance h from the circuit substrate, and h is less than H. The height of the green LEDs and red LEDs are increased, the light emitting surfaces of the green and red LEDs are closer to the display screen, so the display contrast ratios of the green light and the red light are enhanced and can be adaptive to the display contrast ratio of the blue light emitted by the blue LED, and thus the overall color contrast ratio of the LED module is improved.

In some embodiments, another LED module is provided, including a circuit substrate, and at least four red LEDs, at least four green LEDs and at least four blue LEDs provided on the circuit substrate, wherein the red LEDs are arranged in an n*m matrix, the two sides of each row of the red LEDs are provided with blue LEDs and green LEDs, respectively, two sides of each column of the red LEDs are respectively provided with blue LEDs and green LEDs, and n and m are greater than or equal to 2. For a display device, a greater number of LEDs included in a single pixel indicates higher brightness, stronger color contrast, higher resolution and better display effect. In the embodiment, when the LED module includes at least four red LEDs, at least four green LEDs and at least four blue LEDs, in order to render the best color contrast of the LED module, it's necessary to arrange the LEDs of different colors in the LED module, and since the light intensity of the red light is weaker than that of the blue light and the green light, the red LEDs are arranged in an n*m matrix, and the blue light LEDs and the green light LEDs are arranged all around the red light LED matrix, so that the display contrast ratio of the red light is enhanced and adaptive to the display contrast ratios of the blue light and the green light, and the overall color contrast ratio of the LED module is improved.

In some embodiments, one side of the red LEDs is provided with a blue LED alternating with a green LED, and in the embodiment, the four sides of the red LED matrix are provided with a blue LED alternating with a green LED.

In some embodiments, one side of the red LEDs is provided with adjacent blue LEDs or adjacent green LEDs. In some specific embodiments, if the left side of the red LED matrix is provided with adjacent blue LEDs, then the right side of the red LED matrix is provided with adjacent green LEDs; if the upper side of the red LED matrix is provided with adjacent blue LEDs, then the lower side of the red LED matrix is provided with adjacent green LEDs.

In some specific embodiments, the LED module includes four red LEDs, four green LEDs and four blue LEDs, wherein the four red LEDs are arranged in a 2*2 matrix, and the left and right sides of a first and a second rows of the red LEDs are respectively provided with a green LED and a blue LED; the upper and lower sides of a first and a second columns of the red light LEDs are respectively provided with a green light LED and a blue light LED. In the embodiment, since the light intensity of the red light is weaker than that of the blue light and the green light, the display contrast ratio of the red light is enhanced to adapt to the display contrast ratios of the blue light and the green light by arranging the four red LEDs in a 2*2 matrix and arranging the adjacent blue LEDs or the adjacent green LEDs on one side of the red LEDs, and thus the overall color contrast ratio of the LED module is improved.

In some embodiments, as shown in FIG. 5, the LED module includes four red LEDs, four green LEDs and four blue LEDs, wherein the four red LEDs are arranged in a 2*2 matrix, the left and right sides of a first row of red LEDs are respectively provided with a blue LED and a green LED, and the left and right sides of a second row of red LEDs are respectively provided with a green LED and a blue LED; the upper and lower sides of the first column of red light LEDs are respectively provided with a blue light LED and a green light LED, and the upper and lower sides of the second column of red light LEDs are respectively provided with a green light LED and a blue light LED. In the embodiment, since the light intensity of the red light is weaker than that of the blue light and the green light, the display contrast ratio of the red light is enhanced to adapt to the display contrast ratios of the blue light and the green light by arranging the four red light LEDs in a 2*2 matrix and arranging the blue light LEDs alternating with the green light LEDs on the four sides of the red light LED matrix, and thus the overall color contrast ratio of the LED module is improved.

In the red LED matrix of this embodiment, as shown in FIG. 5, in order to enhance the display contrast ratio of the red light, the distance between the two adjacent red LEDs is set as d, the distances from the red LED to the green LED and to the blue LED are set as D, and d is less than D. The distance between the two adjacent red LEDs is smaller than the distance from the red LED to the green LED or to the blue LED, so the red light emitted by the two adjacent red LEDs is concentrated, the display contrast ration of the red light is enhanced and can be adaptive to the display contrast ratios of the blue light emitted by the blue LED and the green light emitted by the green LED, and thus the overall color contrast ratio of the LED module is improved

In the red LED matrix in the embodiment, in order to enhance the display contrast ratio of red light, the light emitting surfaces of the two adjacent red LEDs are disposed at a distance H from the circuit substrate, the light emitting surfaces of the blue LED and the green LED are disposed at a distance h from the circuit substrate, and h is less than H. The height of the red LED is increased, the light emitting surface of the red LED is closer to the display screen, so the display contrast ratio of the red light is enhanced and can be adaptive to the display contrast ratios of the blue light emitted by the blue LED and the green light emitted by the green LED, and thus the overall color contrast ratio of the LED module is improved.

In some embodiments, an LED display device is provided, including the LED module of the present disclosure. By way of example, the LED display device may be any one of an LED display, an LED panel, an LED light source, but is not limited thereto.

In summary, the disclosure provides an LED module, including a circuit substrate, and at least four red LEDs, at least four green LEDs and at least four blue LEDs provided on the circuit substrate, wherein the red LEDs are arranged in an n*m matrix, two sides of each row of the red LEDs are respectively provided with blue LEDs and green LEDs, and two sides of each column of the red LEDs are respectively provided with blue LEDs and green LEDs; and both n and m are greater than or equal to 2. According to the disclosure, the Red-Green-Blue(RGB)LEDs in the LED module are adjusted in the number and arranged with respect to their positions, so that the color contrast and brightness of the LED module are improved.

It is to be understood that the disclosure is not limited in its application to the examples described above and that modifications and variations may be resorted to in light of the above teachings by those skilled in the art, all these modifications and variations falling within the scope of the appended claims.

1. An LED module, comprising a circuit substrate, and red LEDs, green LEDs and blue LEDs provided on the circuit substrate, among which a number of LEDs with at least one color is more than one; the red LEDs, the green LEDs and the blue LEDs being arranged in a same row or a same column, and the LEDs of the same color being adjacently arranged.

2. The LED module according to claim 1, comprising two red LEDs, one green LED and one blue LED, wherein the two red LEDs are arranged adjacent to each other, and the green LED and the blue LED are respectively arranged on two sides of the two adjacent red LEDs.

3. The LED module according to claim 1, comprising two green LEDs, one red LED and one blue LED, wherein the two green LEDs are arranged adjacent to each other, and the red LED and the blue LED are respectively arranged on two sides of the two adjacent green LEDs.

4. The LED module according to claim 1, comprising two red LEDs which are adjacently arranged, two green LEDs which are adjacently arranged and one blue LED, wherein the two adjacent red LEDs and the two adjacent green LEDs are located on two sides of the blue LED.

5. The LED module according to claim 1, wherein a distance between the LEDs of the same color is d, a distance between the LEDs with different colors is D, and d is less than D.

6. The LED module according to claim 1, wherein a distance between light emitting surfaces of the more-than-one LEDs of the same color and the circuit substrate is H, a distance between a light emitting surface of the one-numbered LED and the circuit substrate is h, and h is less than H.

7. The LED module according to claim 6, wherein a preset substrate with a height of a is provided on the circuit substrate, the more-than-one LEDs of the same color and having a height of b are provided on the preset substrate, and a+b=H.

8. An LED module, comprising a circuit substrate, and at least four red LEDs, at least four green LEDs and at least four blue LEDs provided on the circuit substrate, wherein the red LEDs are arranged in an n*m matrix, two sides of each row of the red LEDs are respectively provided with blue LEDs and green LEDs, and two sides of each column of the red LEDs are respectively provided with blue LEDs and green LEDs; and both n and m are greater than or equal to 2.

9. The LED module of claim 8, wherein one side of the red LEDs is provided with a blue LED alternating with a green LED.

10. The LED module of claim 8, wherein one side of the red LEDs is provided with blue LEDs arranged adjacently or green LEDs arranged adjacently.

11. The LED module according to claim 8, comprising four red LEDs, four green LEDs and four blue LEDs, wherein the four red LEDs are arranged in a 2*2 matrix, and the left and right sides of a first row of red LEDs and a second row of red LEDs are respectively provided with a green LED and a blue LED; the upper and lower sides of the first column of red light LEDs and the second column of red light LEDs are respectively provided with a green light LED and a blue light LED.

12. The LED module according to claim 8, comprising four red LEDs, four green LEDs and four blue LEDs, wherein the four red LEDs are arranged in a 2*2 matrix, the left and right sides of a first row of red LEDs are respectively provided with a blue LED and a green LED, and the left and right sides of a second row of red LEDs are respectively provided with a green LED and a blue LED; the upper and lower sides of the first column of red light LEDs are respectively provided with a blue light LED and a green light LED, and the upper and lower sides of the second column of red light LEDs are respectively provided with a green light LED and a blue light LED.

13. The LED module according to claim 8, wherein a distance between the red LEDs is d, a distance from the red LED to the blue LED and to the green LED is D, and d is less than D.

14. The LED module according to claim 8, wherein a distance between light emitting surfaces of the red LEDs and the circuit substrate is H, a distance from light emitting surfaces of the blue LEDs and from the green LEDs to the circuit substrate is h, and h is less than H.

15. An LED display device, comprising the LED module according to claim 1.

16. The LED module according to claim 2, wherein a distance between the LEDs of the same color is d, a distance between the LEDs with different colors is D, and d is less than D.

17. The LED module according to claim 3, wherein a distance between the LEDs of the same color is d, a distance between the LEDs with different colors is D, and d is less than D.

18. The LED module according to claim 2, wherein a distance between light emitting surfaces of the more-than-one LEDs of the same color and the circuit substrate is H, a distance between a light emitting surface of the one-numbered LED and the circuit substrate is h, and h is less than H.

19. The LED module according to claim 9, wherein a distance between the red LEDs is d, a distance from the red LED to the blue LED and to the green LED is D, and d is less than D.

20. The LED module according to claim 9, wherein a distance between light emitting surfaces of the red LEDs and the circuit substrate is H, a distance from light emitting surfaces of the blue LEDs and from the green LEDs to the circuit substrate is h, and h is less than H.
